(19) United States
(12) Patent Application Publication
(10) Pub. No.: US 2023/0261152 A1
(43) Pub. Date: Aug. 17, 2023

(54) DISPLAY DEVICE

(71) Applicant: Samsung Display Co., LTD., Yongin-si (KR)

(72) Inventors: Kyung Seon TAK, Yongin-si (KR); Young Gu KIM, Yongin-si (KR); Bong Sung SEO, Yongin-si (KR)

(73) Assignee: Samsung Display Co., LTD., Yongin-si (KR)

(21) Appl. No.: 17/948,510

(22) Filed: Sep. 20, 2022

(30) Foreign Application Priority Data
Feb. 16, 2022 (KR) 10-2022-0020320

(51) Int. Cl. H01L 33/50; H01L 25/075; H01L 33/62; H01L 33/38

(52) U.S. Cl. CPC H01L 33/505; H01L 25/0753; H01L 33/62; H01L 33/387

(57) ABSTRACT

A display device includes a first light emitting element disposed in a first emission area and forming a first pixel, a second light emitting element disposed in a second emission area and forming a second pixel, a bank layer including a first opening corresponding to the first emission area, a second opening corresponding to the second emission area, and a non-emission area partitioning the first emission area and the second emission area, a first color filter layer disposed on the first light emitting element and the bank layer and including first scatterers, a second color filter layer disposed on the second light emitting element and the bank layer and including second scatterers, and a polarization layer disposed on the first color filter layer and the second color filter layer.

### CROSS-REFERENCE TO RELATED APPLICATION(S)

This application claims priority to and the benefits of Korean Patent Application No. 10-2022-0020320 under 35 U.S.C. 119, filed on Feb. 16, 2022 in the Korean Intellectual Property Office, the entire contents of which are hereby incorporated by reference.

### BACKGROUND

### 1. Technical Field

The disclosure relates to a display device.

### 2. Description of the Related Art

In recent years, as interest in information displays is increasing, research and development related to display devices is continuously conducted.

### SUMMARY

An aspect of the disclosure is to provide a display device including color filter layers disposed on pixels including light emitting elements and a polarization layer disposed on the color filter layers. The color filter may include scatterers.

However, aspects of the disclosure are not limited to the above-described aspect, and may be variously extended without departing from the spirit and scope of the disclosure.

A display device according to an embodiment may include a first light emitting element disposed in a first emission area and forming a first pixel, a second light emitting element disposed in a second emission area and forming a second pixel, a bank layer including a first opening corresponding to the first emission area, a second opening corresponding to the second emission area, and a non-emission area partitioning the first emission area and the second emission area, a first color filter layer disposed on the first light emitting element and the bank layer and including first scatterers, a second color filter layer disposed on the second light emitting element and the bank layer and including second scatterers, and a polarization layer disposed on the first color filter layer and the second color filter layer.

According to an embodiment, the first light emitting element may be a light emitting diode having a size less than or equal to a micro-scale, the first light emitting element emitting light of a first color, and the second light emitting element may be a light emitting diode having a size less than or equal to a micro-scale, the second light emitting element emitting light of a second color different from the first color.

According to an embodiment, the polarization layer may be a coating polarization layer including a dichroic dye.

According to an embodiment, content of the dichroic dye may be greater than about 0.5 wt % and less than about 2 wt % based on a total weight of the polarization layer.

According to an embodiment, content of the first scatterers and content of the second scatterers may be different from each other with respect to a same volume.

According to an embodiment, sizes of the first scatterers and sizes of the second scatterers may be different from each other.

According to an embodiment, the display device may further include a third light emitting element disposed in a third emission area and forming a third pixel, and a third color filter layer disposed on the third light emitting element and the bank layer and including third scatterers, and the bank layer may further include an opening corresponding to the third emission area.

According to an embodiment, the third light emitting element may be a light emitting diode having a size less than or equal to a micro-scale, the third light emitting element emitting light of a third color different from the first color and the second color.

According to an embodiment, the polarization layer may be integrally formed to overlap the first emission area, the second emission area, the third emission area, and the non-emission area.

According to an embodiment, the first color filter layer, the second color filter layer, and the third color filter layer may be sequentially stacked on each other to overlap the bank layer.

According to an embodiment, the polarization layer may be directly disposed on the first color filter layer, the second color filter layer, and the third color filter layer in the first emission area, the second emission area, and the third emission area.

According to an embodiment, content of the first scatterers, content of the second scatterers, and content of the third scatterers may be different from each other with respect to a same volume.

According to an embodiment, each of the first to third pixels may include a first alignment electrode and a second alignment electrode that are disposed to be spaced apart from each other with each of the first to third light emitting elements interposed therebetween, a first pixel electrode electrically connected to the first alignment electrode and an end of each of the first to third light emitting elements, the first pixel electrode disposed on the first alignment electrode with an insulating layer interposed therebetween, and a second pixel electrode electrically connected to the second alignment electrode and another end of each of the first to third light emitting elements, the second pixel electrode disposed on the second alignment electrode with the insulating layer interposed therebetween.

According to an embodiment, the display device may further include an organic insulating layer disposed on the bank layer to fill the first to third openings and planarizing lower surfaces of the first to third color filter layers.

A display device according to an embodiment may include a first light emitting element disposed in a first emission area and forming a first pixel, a second light emitting element disposed in a second emission area and forming a second pixel, a third light emitting element disposed in a third emission area and forming a third pixel, a bank layer including a first opening corresponding to the first emission area, a second opening corresponding to the second emission area, a third opening corresponding to the third emission area, and a non-emission area partitioning the first emission area, the second emission area, and the third emission area, a first color filter layer disposed on the first light emitting element and the bank layer and including first scatterers, a second color filter layer disposed on the second light emitting element and the bank layer and including second scatterers; a third color filter layer disposed on the third light emitting element and the bank layer and including third scatterers, and a coating polarization layer integrally disposed on the first color filter layer, the second color filter layer, and the third color filter layer.

According to an embodiment, the first light emitting element may be a light emitting diode having a size less than or equal to a micro-scale, the first light emitting element emitting light of a first color, the second light emitting element may be a light emitting diode having a size less than or equal to a micro-scale, the second light emitting element emitting light of a second color different from the first color, and the third light emitting element may be a light emitting diode having a size less than or equal to a micro-scale, the third light emitting element emitting light of a third color different from the first color and the second color.

According to an embodiment, the coating polarization layer may include a dichroic dye.

According to an embodiment, content of the dichroic dye may be greater than about 0.5 wt % and less than about 2 wt % based on a total weight of the polarization layer.

According to an embodiment, the first color filter layer, the second color filter layer, and the third color filter layer may be sequentially stacked on each other to overlap the bank layer.

According to an embodiment, the polarization layer may be directly disposed on the first color filter layer, the second color filter layer, and the third color filter layer in the first emission area, the second emission area, and the third emission area.

### BRIEF DESCRIPTION OF THE DRAWINGS

The accompanying drawings, which are included to provide a further understanding of the disclosure, and are incorporated in and constitute a part of this specification, illustrate embodiments, and, together with the description, serve to explain principles of the disclosure.

FIG. 1 is a perspective view schematically illustrating a light emitting element according to an embodiment of the disclosure.

FIG. 2 is a cross-sectional view schematically illustrating an example of the light emitting element of FIG. 1.

FIG. 3 is a plan view schematically illustrating a display device according to an embodiment of the disclosure.

FIG. 4 is a circuit diagram schematically illustrating an example of a pixel included in the display device of FIG. 3.

FIG. 5 is a circuit diagram schematically illustrating an example of the pixel included in the display device of FIG. 3.

FIG. 6 is a circuit diagram schematically illustrating an example of the pixel included in the display device of FIG. 3.

FIG. 7 is a cross-sectional view schematically illustrating an example of a display area of the display device of FIG. 3.

FIG. 8 is a cross-sectional view schematically illustrating an example of the display area of the display device of FIG. 3.

### DETAILED DESCRIPTION OF THE EMBODIMENTS

Hereinafter, embodiments of the disclosure will be described in more detail with reference to the accompanying drawings. The same reference numerals are used for the same elements in the drawings, and duplicate descriptions for the same elements may be omitted.

The embodiments described in the specification are intended to clearly explain the spirit of the disclosure to those of ordinary skill in the art to which the disclosure pertains. Therefore, the disclosure is not limited by the embodiments described in the specification, and the scope of the disclosure should be construed to include modifications or variations that do not depart from the spirit of the disclosure.

The accompanying drawings in the specification are for easily explaining the disclosure. Since the shapes shown in the drawings may be exaggerated as necessary to help the understanding of the disclosure, the disclosure is not limited by the drawings.

It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the disclosure. Similarly, the second element could also be termed the first element.

It will be further understood that the terms “comprise”, “include”, “have”, etc. used in the disclosure, specify the presence of stated features, integers, steps, operations, elements, components, and/or combinations of them but do not preclude the presence or addition of one or more other features, integers, steps, operations, elements, components, and/or combinations thereof. In addition, when a first part such as a layer, film, region, etc. is on a second part, the first part may be not only “directly on” the second part but a third part may intervene between them. Furthermore, in the disclosure, when a first part such as a layer, film, region, etc. is formed on a second part, a direction in which the first part is formed is not limited to an upper direction of the second part, but may include a side or a lower direction of the second part. When a first part such as a layer, film, region, etc. is “under” a second part, the first part may be not only “directly under” the second part but a third part may intervene between them.

In the specification, when it is determined that a detailed description of a known configuration or function related to the disclosure may obscure the gist of the disclosure, a detailed description thereof will be omitted. In the disclosure, the singular expressions are intended to include the plural expressions as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

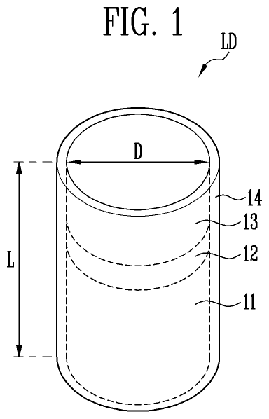

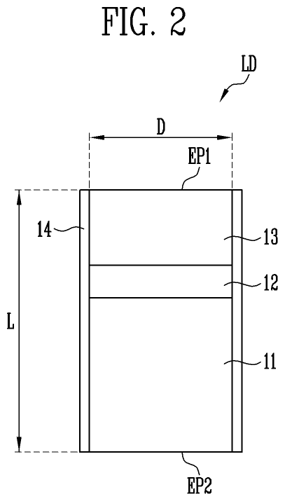

FIG. 1 is a perspective view schematically illustrating a light emitting element according to an embodiment of the disclosure. FIG. 2 is a cross-sectional view schematically illustrating an example of the light emitting element of FIG. 1.

In embodiments, the type and/or shape of a light emitting element LD is not limited to the embodiments shown in FIGS. 1 and 2.

Referring to FIGS. 1 and 2, the light emitting element LD may include a first semiconductor layer 11, a second semiconductor layer 13, and an active layer 12 interposed between the first and second semiconductor layers 11 and 13. For example, the light emitting element LD may be implemented as a light emitting laminate (or a laminated pattern) in which the first semiconductor layer 11, the active layer 12, and the second semiconductor layer 13 may be sequentially stacked on each other.

The light emitting element LD may be provided in a shape extending in a direction. In case that a direction in which the light emitting element LD extends is referred to as a longitudinal direction, the light emitting element LD may include a first end EP1 and a second end EP2 along the longitudinal direction. One of the first semiconductor layer 11 and the second semiconductor layer 13 may be positioned at the first end EP1 of the light emitting element LD, and the other of the first semiconductor layer 11 and the second semiconductor layer 13 may be positioned at the second end EP2 of the light emitting element LD. For example, the second semiconductor layer 13 may be positioned at the first end EP1 of the light emitting element LD, and the first semiconductor layer 11 may be positioned at the second end EP2 of the light emitting element LD.

The light emitting element LD may be provided in various shapes. For example, as shown in FIG. 1, the light emitting element LD may have a rod-like shape, a bar-like shape, or a column-like shape that may be long in the longitudinal direction (or has an aspect ratio greater than 1). As another example, the light emitting element LD may have a rod-like shape, a bar-like shape, or a column-like shape that may be short in the longitudinal direction (or has an aspect ratio less than 1). As another example, the light emitting element LD may have a rod-like shape, a bar-like shape, or a column-like shape having an aspect ratio of 1.

The light emitting element LD may include, for example, a light emitting diode (LED) manufactured in an ultra-small size having a diameter D and/or a length L of a nano-scale (or nano-meter) to a micro-scale (or micro-meter).

In case that the light emitting element LD is long in the longitudinal direction (for example, the aspect ratio is greater than 1), the diameter D of the light emitting element LD may be about 0.5 μm to about 6 μm, and the length L thereof may be about 1 μm to about 10 μm. However, the diameter D and the length L of the light emitting element LD are not limited thereto. The size of the light emitting element LD may be changed to meet the requirements (or design conditions) of a lighting device or a self-light emitting display device to which the light emitting element LD may be applied.

The first semiconductor layer 11 may include, for example, at least one n-type semiconductor layer. For example, the first semiconductor layer 11 may be an n-type semiconductor layer including at least one semiconductor material of InAlGaN, GaN, AlGaN, InGaN, AlN, and InN, and doped with a first conductive dopant (or an n-type dopant) such as Si, Ge, Sn, and/or the like. However, the material constituting the first semiconductor layer 11 is not limited thereto, and the first semiconductor layer 11 may be formed of various other materials. The first semiconductor layer 11 may include an upper surface in contact with the active layer 12 and a lower surface exposed to outside along the longitudinal direction of the light emitting element LD. The lower surface of the first semiconductor layer 11 may be an end (or lower end) of the light emitting element LD.

The active layer 12 may be disposed on the first semiconductor layer 11 and may be formed in a single or multiple quantum well structure. For example, in case that the active layer 12 is formed in a multi-quantum well structure, the active layer 12 may have a structure in which a barrier layer, a strain reinforcing layer, and a well layer may be periodically and repeatedly stacked on each other as a unit. Since the strain reinforcing layer has a smaller lattice constant than the barrier layer, a strain applied to the well layer, for example, a compressive strain, may be further strengthened. However, the structure of the active layer 12 is not limited to the above-described embodiment.

The active layer 12 may emit light having the wavelength of 400 nm to 900 nm, and a double hetero structure may be applied. In an embodiment, a clad layer doped with a conductive dopant may be formed on the upper and/or lower portions of the active layer 12 in the longitudinal direction of the light emitting element LD. For example, the clad layer may be formed of an AlGaN layer, an InAlGaN layer, a GaAs layer, or the like, or a combination thereof. According to an embodiment, a material such as AlGaN, InAlGaN, GaAs, or the like, or a combination thereof may be used to form the active layer 12. Various other materials may be used to form the active layer 12. The active layer 12 may include a first surface in contact with the first semiconductor layer 11 and a second surface in contact with the second semiconductor layer 13.

In an embodiment, the color (or output color) of the light emitting element LD may be determined according to the wavelength of light emitted from the active layer 12. The color of the light emitting element LD may determine the color of a corresponding pixel. For example, the light emitting element LD may emit red light, green light, or blue light.

In case that an electric field greater than a voltage is applied to both ends of the light emitting element LD, the light emitting element LD may emit light while electron-hole pairs may be combined in the active layer 12. By controlling the light emitting of the light emitting element LD using this principle, the light emitting element LD can be used as a light source (or light emitting source) of various light emitting devices including pixels of a display device.

The second semiconductor layer 13 may be disposed on the second surface of the active layer 12, and may include a semiconductor layer of a different type from that of the first semiconductor layer 11. For example, the second semiconductor layer 13 may include at least one p-type semiconductor layer. For example, the second semiconductor layer 13 may include a p-type semiconductor layer including at least one semiconductor material of InAlGaN, GaN, AlGaN, InGaN, AlN, and InN, and doped with a second conductive dopant (or p-type dopant) such as Mg, Zn, Ca, Sr, Ba, and/or the like. However, the material constituting the second semiconductor layer 13 is not limited thereto. Various other materials may be used to form the second semiconductor layer 13. The second semiconductor layer 13 may include a lower surface in contact with the second surface of the active layer 12 along the longitudinal direction of the light emitting device LD and an upper surface exposed to the outside. Here, the upper surface of the second semiconductor layer 13 may be another end (or upper end) of the light emitting element LD.

In an embodiment, the first semiconductor layer 11 and the second semiconductor layer 13 may have different thicknesses in the longitudinal direction of the light emitting element LD. For example, the first semiconductor layer 11 may have a relatively greater thickness than the second semiconductor layer 13 in the longitudinal direction of the light emitting element LD. Accordingly, the active layer 12 of the light emitting element LD may be positioned closer to the upper surface of the second semiconductor layer 13 than to the lower surface of the first semiconductor layer 11.

Although an embodiment in which each of the first semiconductor layer 11 and the second semiconductor layer 13 may be composed of one layer is shown, the disclosure is not limited thereto. In an embodiment, depending on the material of the active layer 12, each of the first semiconductor layer 11 and the second semiconductor layer 13 may further include at least one or more layers, for example, a clad layer and/or a tensile strain barrier reducing (TSBR) layer. The TSBR layer may be a strain relief layer disposed between semiconductor layers having different lattice structures to serve as a buffer to reduce a lattice constant difference. The TSBR layer may be formed of a p-type semiconductor layer such as p-GaInP, p-AlInP, p-AlGaInP, or the like, but the disclosure is not limited thereto.

According to an embodiment, the light emitting element LD may further include a contact electrode (hereinafter, referred to as a first contact electrode) disposed on the second semiconductor layer 13 in addition to the first semiconductor layer 11, the active layer 12, and the second semiconductor layer 13 described above. According to another embodiment, the light emitting element LD may further include another contact electrode (hereinafter, referred to as a second contact electrode) disposed on an end of the first semiconductor layer 11.

Each of the first and second contact electrodes may be an ohmic contact electrode, but the disclosure is not limited thereto. According to an embodiment, the first and second contact electrodes may be Schottky contact electrodes. The first and second contact electrodes may include a conductive material. For example, the first and second contact electrodes may include opaque metal including chromium (Cr), titanium (Ti), aluminum (Al), gold (Au), nickel (Ni), and oxides or alloys thereof alone or in combination, but the disclosure is not limited thereto. According to an embodiment, the first and second contact electrodes may include a transparent conductive oxide such as indium tin oxide (ITO), indium zinc oxide (IZO), zinc oxide (ZnOx), indium gallium zinc oxide (IGZO), and/or indium tin zinc oxide (ITZO). Here, the zinc oxide (ZnOx) may be zinc oxide (ZnO) and/or zinc peroxide (ZnO₂).

The materials included in the first and second contact electrodes may be the same as or different from each other. The first and second contact electrodes may be substantially transparent or translucent. Accordingly, light generated by the light emitting element LD may pass through each of the first and second contact electrodes and may be emitted to the outside of the light emitting element LD. According to an embodiment, in case that the light generated by the light emitting element LD is emitted to the outside of the light emitting element LD through an area excluding the ends of the light emitting element LD without passing through the first and second contact electrodes, the first and second contact electrodes may include an opaque metal.

In an embodiment, the light emitting element LD may further include an insulating film 14 (or an insulating thin film). However, according to an embodiment, the insulating film 14 may be omitted, or provided to cover only a portion of the first semiconductor layer 11, the active layer 12, and the second semiconductor layer 13.

The insulating film 14 may prevent an electrical short circuit that may occur in case that the active layer 12 comes into contact with a conductive material other than the first and second semiconductor layers 11 and 13. The insulating film 14 may minimize surface defects of the light emitting element LD to improve the lifespan and light emitting efficiency of the light emitting element LD. In case that light emitting elements LD are disposed adjacent to each other, the insulating film 14 may prevent an unwanted short circuit that may occur between the light emitting elements LD. The presence or absence of the insulating film 14 is not limited as long as the active layer 12 can be prevented from being short-circuited with an external conductive material.

The insulating film 14 may be provided in a form that entirely surrounds an outer peripheral surface of the light emitting laminate including the first semiconductor layer 11, the active layer 12, and the second semiconductor layer 13.

In the above-described embodiment, although a structure in which the insulating film 14 entirely surrounds outer peripheral surfaces of the first semiconductor layer 11, the active layer 12, and the second semiconductor layer 13 has been described, the disclosure is not limited thereto. According to an embodiment, in case that the light emitting element LD includes the first contact electrode, the insulating film 14 may entirely surround outer peripheral surfaces of the first semiconductor layer 11, the active layer 12, the second semiconductor layer 13, and the first contact electrode. According to another embodiment, the insulating film 14 may not entirely surround the outer peripheral surface of the first contact electrode, or may surround only a portion of the outer peripheral surface of the first contact electrode, and may not surround the remaining portion of the outer peripheral surface of the first contact electrode. According to an embodiment, in case that the first contact electrode is disposed at the other end (or upper end) of the light emitting element LD and the second contact electrode is disposed at an end (or lower end) of the light emitting element LD, the insulating film 14 may expose at least a portion of each of the first and second contact electrodes.

The insulating film 14 may include a transparent insulating material. For example, the insulating film 14 may include at least one insulating material selected from the group consisting of silicon oxide (SiOx), silicon nitride (SiNx), silicon oxynitride (SiOxNy), aluminum oxide (AlOx), titanium oxide (TiOx), hafnium oxide (HfOx), titanium strontium oxide (SrTiOx), cobalt oxide (CoxOy), magnesium oxide (MgO), zinc oxide (ZnOx), ruthenium oxide (RuOx), nickel oxide (NiO), tungsten oxide (WOx), tantalum oxide (TaOx), gadolinium oxide (GdOx), zirconium oxide (ZrOx), gallium oxide (GaOx), vanadium oxide (VxOy), ZnO:Al, ZnO:B, InxOy:H, niobium oxide (NbxOy), magnesium fluoride (MgFX), aluminum fluoride (AlFx), alucone polymer film, titanium nitride (TiN), tantalum nitride (TaN), aluminum nitride (AlNX), gallium nitride (GaN), tungsten nitride (WN), hafnium nitride (HfN), niobium nitride (NbN), gadolinium nitride (GdN), zirconium nitride (ZrN), vanadium nitride (VN), and the like. However, the disclosure is not limited thereto, and various other materials having insulating properties may be used as the material of the insulating film 14.

The insulating film 14 may be provided in a form of a single layer or may be provided in a form of a multi-layer including a double layer. For example, in case that the insulating film 14 is composed of a double layer including a first insulating layer and a second insulating layer sequentially stacked on each other, the first insulating layer and the second insulating layer may include different materials and may be formed by different processes. According to an embodiment, the first insulating layer and the second insulating layer may include the same material and may be formed by successive processes.

According to an embodiment, the light emitting element LD may be implemented as a light emitting pattern having a core-shell structure. The above-described first semiconductor layer 11 may be positioned in the core, for example, in the middle (or center) of the light emitting element LD, the active layer 12 may be provided and/or formed to surround the outer peripheral surface of the first semiconductor layer 11, and the second semiconductor layer 13 may be provided and/or formed to surround the active layer 12. The light emitting element LD may further include a contact electrode (not shown) surrounding at least one side of the second semiconductor layer 13. Also, according to an embodiment, the light emitting element LD may further include the insulating film 14 provided on an outer peripheral surface of the light emitting pattern having the core-shell structure, and including a transparent insulating material. The light emitting element LD implemented as the light emitting pattern having the core-shell structure may be manufactured by a growth method.

The above-described light emitting element LD may be used as a light emitting source (or light source) of various display devices. The light emitting element LD may be manufactured through a surface treatment process. For example, in case that light emitting elements LD are mixed in a fluid solution (or solvent) and supplied to each pixel area (for example, an emission area of each pixel or an emission area of each sub-pixel), each of the light emitting elements LD may be surface-treated so that the light emitting elements LD may be uniformly sprayed without being non-uniformly aggregated in the solution.

An emission unit (or a light emitting device) including the above-described light emitting element LD may be used in various types of electronic devices requiring a light source, such as a display device. For example, in case that multiple light emitting elements LD are disposed in a pixel area of each pixel of a display panel, the light emitting elements LD may be used as light sources of each pixel. However, fields to which the light emitting element LD may be applied are not limited to the above-described examples. For example, the light emitting element LD may also be used in other types of electronic devices requiring a light source, such as a lighting device.

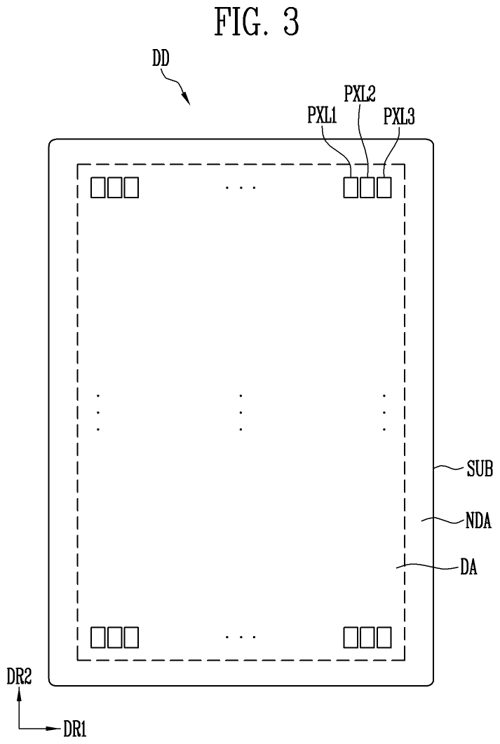

FIG. 3 is a plan view schematically illustrating a display device according to an embodiment of the disclosure.

If a display device DD is an electronic device having a display surface on at least one surface, such as a smartphone, a television, a tablet PC, a mobile phone, a video phone, an e-book reader, a desktop PC, a laptop PC, a netbook computer, a workstation, a server, a PDA, a PMP (portable multimedia player), an MP3 player, a medical device, a camera, or a wearable device, the disclosure may be applied.

Referring to FIGS. 1 to 3, the display device DD may include a substrate SUB, pixels PXL1, PXL2, and PXL3 provided on the substrate SUB and each including at least one light emitting element LD, a driving unit provided on the substrate SUB and driving the pixels PXL1, PXL2, and PXL3, and a wiring unit connecting the pixels PXL1, PXL2, and PXL3 and the driving unit.

The substrate SUB may include a display area DA and a non-display area NDA.

The display area DA may be an area in which the pixels PXL1, PXL2, and PXL3 displaying an image may be provided. The non-display area NDA may be an area in which the driving unit for driving the pixels PXL1, PXL2, and PXL3 and a portion of the wiring unit connecting the pixels PXL1, PXL2, and PXL3 and the driving unit may be provided.

The non-display area NDA may be located adjacent to the display area DA. The non-display area NDA may be provided on at least one side of the display area DA. For example, the non-display area NDA may surround an outer portion (or an edge) of the display area DA.

The wiring unit may electrically connect the driving unit and the pixels PXL1, PXL2, and PXL3. The wiring unit may provide signals to the pixels PXL1, PXL2, and PXL3, and may include a fan-out line connected to signal lines connected to each of the pixels PXL1, PXL2, and PXL3, for example, a scan line, a data line, an emission control line, and the like.

The substrate SUB may include a transparent insulating material to transmit light. The substrate SUB may be a rigid substrate or a flexible substrate.

Each of the pixels PXL1, PXL2, and PXL3 may be provided in the display area DA on the substrate SUB.

The pixels PXL1, PXL2, and PXL3 may include a first pixel PXL1, a second pixel PXL2, and a third pixel PXL3. In an embodiment, the first pixel PXL1 may be a red pixel, the second pixel PXL2 may be a green pixel, and the third pixel PXL3 may be a blue pixel. However, the disclosure is not limited thereto, and the pixels PXL1, PXL2, and PXL3 may emit light of colors other than red, green, and blue, respectively.

Each of the pixels PXL1, PXL2, and PXL3 may include at least one light emitting element LD driven by a corresponding scan signal and data signal. The light emitting element LD may have a size as small as a nano-scale (or nano-meter) to a micro-scale (or micro-meter), and may be connected in parallel to adjacent light emitting elements, but the disclosure is not limited thereto. The light emitting element LD may constitute a light source of each of the pixels PXL1, PXL2, and PXL3.

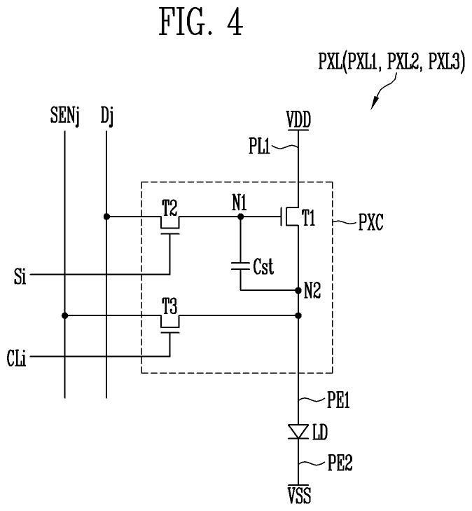

FIG. 4 is a circuit diagram schematically illustrating an example of a pixel included in the display device of FIG. 3.

In the following embodiments, when the first pixel PXL1, the second pixel PXL2, and the third pixel PXL3 are arbitrarily referred to, they may be referred to as a pixel PXL.

Referring to FIGS. 1, 2, 3, and 4, the pixel PXL may include a pixel circuit PXC and a light emitting element LD.

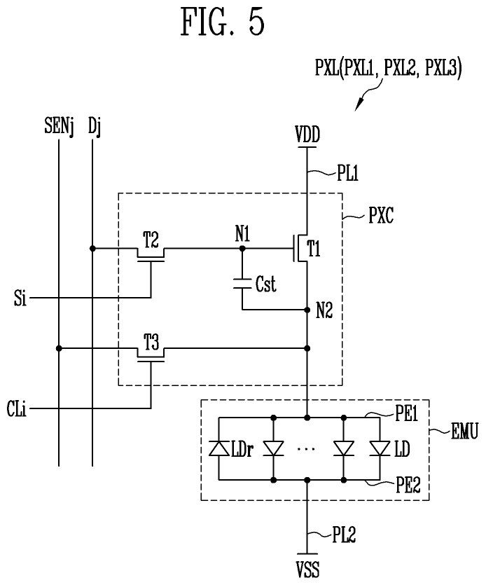

The light emitting element LD may be connected between a first power source line PL1 to which a voltage of a first driving power source VDD may be applied and a second power source line (for example, shown as PL2 in FIG. 5) to which a voltage of a second driving power source VSS may be applied. For example, the light emitting element LD may include a first pixel electrode PE1 (or first electrode) connected to the first driving power source VDD via the first power source line PL1 and a second pixel electrode PE2 (or second electrode) connected to the second driving power source VSS via the second power source line PL2. In an embodiment, the first pixel electrode PE1 may be an anode, and the second pixel electrode PE2 may be a cathode.

The light emitting element LD may include an end connected to the first driving power source VDD through the first pixel electrode PE1 and the other end connected to the second driving power source VSS through the second pixel electrode PE2. The first driving power source VDD and the second driving power source VSS may have different potentials. For example, the first driving power source VDD may be set as a high potential power source, and the second driving power source VSS may be set as a low potential power source. A potential difference between the first and second driving power sources VDD and VSS may be set to be greater than or equal to a threshold voltage of light emitting elements during an emission period of the pixel PXL.

The pixel circuit PXC may be connected to a scan line Si (where i may be a positive integer) and a data line Dj (where j may be a positive integer) of the pixel PXL. Also, the pixel circuit PXC may be connected to a control line CLi and a sensing line SENj of the pixel PXL. For example, in case that the pixel PXL is disposed in an i-th row and a j-th column in the display area DA, the pixel circuit PXC of the pixel PXL may be connected to an i-th scan line Si, a j-th data line Dj, an i-th control line CLi, and a j-th sensing line SENj in the display area DA.

The pixel circuit PXC may include first to third transistors T1 to T3 and a storage capacitor Cst.

The first transistor T1 may be a driving transistor for controlling a driving current applied to the light emitting element LD. The first transistor T1 may be connected between the first driving power source VDD and the light emitting element LD. A gate electrode of the first transistor T1 may be connected to a first node N1.

The first transistor T1 may control the amount of the driving current applied from the first driving power source VDD to the light emitting element LD through a second node N2 according to a voltage applied to the first node N1.

The second transistor T2 may be a switching transistor that selects the pixel PXL in response to a scan signal and activates the pixel PXL. The second transistor T2 may be connected between the data line Dj and the first node N1. A gate electrode of the second transistor T2 may be connected to the scan line Si.

The second transistor T2 may be turned on by the scan signal supplied to the scan line Si, and may transfer a data signal to the gate electrode of the first transistor T1.

The third transistor T3 may obtain a sensing signal through the sensing line SENj by connecting the first transistor T1 to the sensing line SENj, and may detect characteristics of the pixel PXL, such as a threshold voltage of the first transistor T1 or the like, using the sensing signal. Information on the characteristics of the pixel PXL may be used to convert image data so that a characteristic deviation between pixels can be compensated.

The third transistor T3 may be connected between the sensing line and the second node N2. A gate electrode of the third transistor T3 may be connected to the control line CLi.

In an embodiment, a voltage of an initialization power source may be provided for a period through the sensing line SENj. The third transistor T3 may be turned on in case that a sensing control signal is supplied from the control line CLi to transfer the voltage of the initialization power source to the second node N2. Accordingly, a voltage stored in the storage capacitor Cst connected to the second node N2 may be initialized.

The storage capacitor Cst may be connected between the first node N1 and the second node N2. The storage capacitor Cst may be charged with a data voltage corresponding to the data signal supplied to the first node N1 during one frame period. Accordingly, the storage capacitor Cst may store a voltage corresponding to a difference between a voltage of the gate electrode of the first transistor T1 and a voltage of the second node N2.

FIG. 5 is a circuit diagram schematically illustrating an example of the pixel included in the display device of FIG. 3.

In FIG. 5, the same reference numerals are used for the same or similar components as those described with reference to FIG. 4, and duplicate descriptions thereof will be omitted. A pixel PXL of FIG. 5 may be substantially the same as or similar to the pixel PXL of FIG. 4 except for a configuration of an emission unit EMU.

Referring to FIGS. 1, 2, 3, and 5, the pixel PXL may include a pixel circuit PXC and an emission unit EMU.

In an embodiment, the emission unit EMU may include light emitting elements LD connected in parallel between a first power source line PL1 and a second power source line PL2. Each of the light emitting elements LD may include a first pixel electrode PE1 and a second pixel electrode PE2. Each of the light emitting elements LD connected in parallel in the same direction (for example, a forward direction) between the first pixel electrode PE1 and the second pixel electrode PE2 may be an effective light source.

In an embodiment, the emission unit EMU may further include at least one ineffective light source, for example, a reverse light emitting element LDr. The reverse light emitting element LDr may be connected between the first and second pixel electrodes PE1 and PE2 in an opposite direction to the light emitting elements LD. The reverse light emitting element LDr may be maintained in a deactivated state even in case that a driving voltage (for example, a forward driving voltage) is applied between the first and second pixel electrodes PE1 and PE2. Accordingly, substantially no current may flow through the reverse light emitting element LDr.

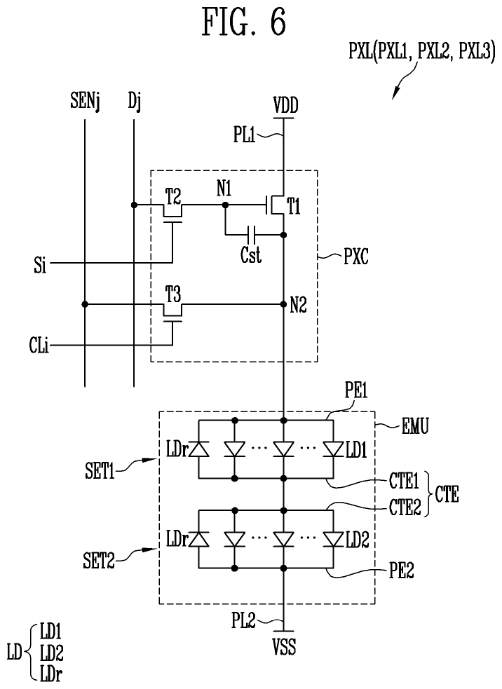

FIG. 6 is a circuit diagram schematically illustrating an example of the pixel included in the display device of FIG. 3.

In FIG. 6, the same reference numerals are used for the same or similar components as those described with reference to FIGS. 4 and 5, and duplicate descriptions thereof will be omitted. A pixel PXL of FIG. 6 may be substantially the same as or similar to the pixels PXL of FIGS. 4 and 5 except for a configuration of an emission unit EMU.

Referring to FIGS. 1, 2, 3, and 6, the pixel PXL may include a pixel circuit PXC and an emission unit EMU.

In an embodiment, the emission unit EMU may be configured to include at least one series stage including light emitting elements LD connected in parallel. For example, as shown in FIG. 6, the emission unit EMU may be configured in a series/parallel mixed structure.

The emission unit EMU may include first and second series stages SET1 and SET2 connected in series between first and second driving power sources VDD and VSS. Each of the first and second series stages SET1 and SET2 may include two electrodes PE1 and CTE1 and CTE2 and PE2 constituting an electrode pair of a corresponding series stage, and light emitting elements LD connected in parallel in the same direction between the two electrodes PE1 and CTE1 and CTE2 and PE2.

The first series stage SET1 (or a first stage) may include a first pixel electrode PE1, a first intermediate electrode CTE1, and at least one first light emitting element LD1 connected between the first pixel electrode PE1 and the first intermediate electrode CTE1. Also, the first series stage SET1 may include a reverse light emitting element LDr connected in an opposite direction to the first light emitting element LD1 between the first pixel electrode PE1 and the first intermediate electrode CTE1.

The second series stage SET2 (or a second stage) may include a second intermediate electrode CTE2, a second pixel electrode PE2, and at least one second light emitting element LD2 connected between the second intermediate electrode CTE2 and the second pixel electrode PE2. Also, the second series stage SET2 may include a reverse light emitting element LDr connected in an opposite direction to the second light emitting element LD2 between the second intermediate electrode CTE2 and the second pixel electrode PE2.

The first intermediate electrode CTE1 and the second intermediate electrode CTE2 may be electrically and/or physically connected to each other. The first intermediate electrode CTE1 and the second intermediate electrode CTE2 may constitute an intermediate electrode CTE electrically connecting the first series stage SET1 and the second series stage SET2.

In the above-described embodiment, the first pixel electrode PE1 of the first series stage SET1 may be an anode of the pixel PXL, and the second pixel electrode PE2 of the second series stage SET2 may be a cathode of the pixel PXL.

As described above, the emission unit EMU of the pixel PXL including the series stages SET1 and SET2 connected in the series/parallel mixed structure may easily adjust the driving current/voltage condition according to specifications of an applied product.

In particular, the emission unit EMU having the series/parallel mixed structure of FIG. 6 may reduce the driving current compared to an emission unit having a structure in which light emitting elements LD may be connected only in parallel. The emission unit EMU having the series/parallel mixed structure of FIG. 6 may reduce the driving voltage applied to both ends of the emission unit EMU compared to an emission unit having a structure in which the same number of light emitting elements LD may all be connected in series. Furthermore, the emission unit EMU having the series/parallel mixed structure of FIG. 6 may include a larger number of light emitting elements LD between the same number of electrodes PE1, CTE1, CTE2, and PE2 compared to an emission unit having a structure in which series stages may all be connected in series. Light output efficiency of the light emitting elements LD can be improved. Even if a defect occurs in a specific serial stage, a ratio of light emitting elements LD that do not emit light due to the defect may be relatively reduced. Accordingly, a problem in which the light output efficiency of the light emitting elements LD may be lowered can be alleviated.

FIGS. 4, 5, and 6 show an embodiment in which the first, second, and third transistors T1, T2, and T3 included in the pixel circuit PXC may all be N-type transistors, but the disclosure is not limited thereto. For example, at least one of the first, second, and third transistors T1, T2, and T3 may be changed to a P-type transistor. FIGS. 5 and 6 show an embodiment in which the emission unit EMU may be connected between the pixel circuit PXC and the second driving power source VSS, the emission unit EMU may be connected between the first driving power source VDD and the pixel circuit PXC.

Furthermore, a configuration of the pixel circuit PXC may be modified and applied in various known forms.

The pixel PXL may have various structures. For example, the pixel PXL may be configured inside a passive light emitting display device or the like. The pixel circuit PXC may be omitted, and both ends of the light emitting elements LD included in the emission unit EMU may be directly connected to the scan line Si, the data line Dj, the first power source line PL1 to which the first driving power source VDD may be applied, the second power source line PL2 to which the second driving power source VSS may be applied, and/or a control line.

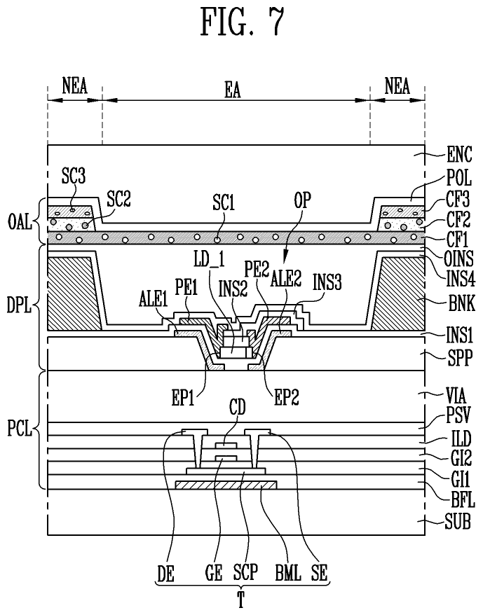

FIG. 7 is a cross-sectional view schematically illustrating an example of a display area of the display device of FIG. 3.

In describing embodiments, the expression “formed and/or provided on the same layer” may mean formed in the same process, and the expression “formed and/or provided on a different layer” may mean formed in different processes.

In FIG. 7, as an example of circuit elements that may be disposed in a pixel circuit layer PCL of each of the first, second, and third pixels PXL1, PXL2, and PXL3, a cross-section of one transistor T (for example, a transistor including a lower metal line BML) included in a pixel circuit PXC is shown as an example. Also, FIG. 7 shows a cross-section of a representative light emitting element LD_1 as an example of the emission unit EMU. For example, the light emitting element LD_1 may emit one of red, green, and blue light.

The first pixel PXL1, the second pixel PXL2, and the third pixel PXL3 disposed in the display area DA may have substantially similar cross-sectional structures to each other. However, the size, position, and/or shape of circuit elements constituting each of the first pixel PXL1, the second pixel PXL2, and the third pixel PXL3 and electrodes included in the circuit elements may be different for each pixel PXL.

Referring to FIGS. 1, 2, 3, and 7, the display device DD (or display panel) may include the substrate SUB, the pixel circuit layer PCL, a display element layer DPL, an optical auxiliary layer OAL, and an encapsulation layer ENC (or protective layer).

The substrate SUB may include a transparent insulating material to transmit light. The substrate SUB may be a rigid substrate or a flexible substrate.

The rigid substrate may be, for example, at least one of a glass substrate, a quartz substrate, a glass ceramic substrate, and a crystalline glass substrate. The flexible substrate may be one of a film substrate including a polymer organic material and a plastic substrate.

The pixel circuit layer PCL may include circuit elements (for example, a transistor T) constituting the pixel circuit PXC of a corresponding pixel PXL and signal lines electrically connected to the circuit elements.

The pixel circuit layer PCL may further include at least one insulating layer in addition to the circuit elements and the signal lines. For example, the pixel circuit layer PCL may include a buffer layer BFL, a first gate insulating layer GI1, a second gate insulating layer GI2, an interlayer insulating layer ILD, a passivation layer PSV, and a via layer VIA sequentially stacked on each other on the substrate SUB.

The buffer layer BFL may be disposed on an entire surface of the substrate SUB. The buffer layer BFL may prevent impurities from diffusing into transistors T1, T2, and T3 included in the pixel circuit PXC. The buffer layer BFL may be an inorganic insulating layer including an inorganic material. The buffer layer BFL may include at least one of silicon nitride (SiNx), silicon oxide (SiOx), silicon oxynitride (SiOxNy), and a metal oxide such as aluminum oxide (AlOx). The buffer layer BFL may be provided as a single layer, or may be provided as a multi-layer including at least a double layer.

The first gate insulating layer GI1 may be disposed on an entire surface of the buffer layer BFL. The first gate insulating layer GI1 may be an inorganic insulating layer including an inorganic material.

The second gate insulating layer GI2 may be disposed on an entire surface of the first gate insulating layer GI1. The second gate insulating layer GI2 may include the same material as the first gate insulating layer GI1 or may include at least one material selected from materials constituting the first gate insulating layer GI1.

The interlayer insulating layer ILD may be provided on an entire surface of the second gate insulating layer GI2. The interlayer insulating layer ILD may include the same material as the first gate insulating layer GI1 or may include at least one material selected from materials constituting the first gate insulating layer GI1.

The passivation layer PSV may be provided and/or formed on an entire surface of the interlayer insulating layer ILD. The passivation layer PSV may be an inorganic insulating layer including an inorganic material or an organic insulating layer including an organic material. The inorganic insulating layer may include, for example, at least one of silicon oxide (SiOx), silicon nitride (SiNx), silicon oxynitride (SiOxNy), and a metal oxide such as aluminum oxide (AlOx). The organic insulating layer may include, for example, at least one of an acrylic resin (polyacrylates resin), an epoxy resin, a phenolic resin, a polyamides resin, a polyimides resin, an unsaturated polyesters resin, a poly-phenylen ethers resin, a poly-phenylene sulfides resin, and a benzocyclobutene resin.

The via layer VIA may be provided on an entire surface of the passivation layer PSV. The via layer VIA may be composed of a single layer including an organic layer or a multi-layer including at least a double layer. According to an embodiment, the via layer VIA may be provided in a form including an inorganic layer and an organic layer disposed on the inorganic layer. In case that the via layer VIA is provided as a multi-layer including at least a double layer, the organic layer constituting the via layer VIA may be positioned on the uppermost layer. The via layer VIA may include at least one of an acrylic resin (polyacrylates resin), an epoxy resin, a phenolic resin, a polyamides resin, a polyimides resin, an unsaturated polyesters resin, a poly-phenylen ethers resin, a poly-phenylene sulfides resin, and a benzocyclobutene resin.

In an embodiment, the via layer VIA may be utilized as a planarization layer for alleviating a step difference generated by components of the pixel circuit PXC positioned below the via layer PCL in the pixel circuit layer PCL.

The pixel circuit layer PCL may include at least one conductive layer disposed between the above-described insulating layers. Each of the conductive layers may be formed of a single layer including one or a mixture thereof selected from the group consisting of copper (Cu), molybdenum (Mo), tungsten (W), aluminum neodymium (AlNd), titanium (Ti), aluminum (Al), silver (Ag), and alloys thereof, or may be formed of a double layer or multi-layer structure including a low-resistance material such as molybdenum (Mo), titanium (Ti), copper (Cu), aluminum (Al), and/or silver (Ag) to reduce wiring resistance.

In an embodiment, the transistor T may be a driving transistor for controlling the driving current of the light emitting element LD, and may have the same configuration as the first transistor T1 described with reference to FIG. 4.

The transistor T may include a semiconductor pattern SCP, a gate electrode GE overlapping a portion of the semiconductor pattern SCP, and source and drain electrodes SE and DE connected to the semiconductor pattern SCP.

The semiconductor pattern SCP may be provided on the buffer layer BFL. For example, the semiconductor pattern SCP may be positioned between the buffer layer BFL and the first gate insulating layer GI1. The semiconductor pattern SCP may be a semiconductor layer made of polysilicon, amorphous silicon, an oxide semiconductor, and/or the like. The semiconductor pattern SCP may include an active pattern, a first contact region, and a second contact region. For example, the first contact region and the second contact region may be formed of a semiconductor layer doped with impurities, and the active pattern may be formed of a semiconductor layer not doped with impurities.

The active pattern of the semiconductor pattern SCP may be a region overlapping a gate electrode GE of the transistor T, and may be a channel region. The first contact region of the semiconductor pattern SCP may be connected to a source electrode SE. The second contact region of the semiconductor pattern SCP may be connected to a drain electrode DE.

The gate electrode GE may be provided on the first gate insulating layer GI1. The gate electrode GE may overlap the active pattern of the semiconductor pattern SCP.

The source electrode SE may be provided on the interlayer insulating layer ILD. The source electrode SE may be in contact with the first contact region of the semiconductor pattern SCP through a contact hole penetrating the first gate insulating layer GI1, the second gate insulating layer GI2, and the interlayer insulating layer ILD.

The drain electrode DE may be provided on the interlayer insulating layer ILD. The drain electrode DE may be disposed on the interlayer insulating layer ILD to be spaced apart from the source electrode SE. The drain electrode DE may be in contact with the second contact region of the semiconductor pattern SCP through a contact hole penetrating the first gate insulating layer GI1, the second gate insulating layer GI2, and the interlayer insulating layer ILD.

In an embodiment, the second gate insulating layer GI2 may cover the gate electrode GE, and a conductive pattern CD may be disposed on the second gate insulating layer GI2. For example, the conductive pattern CD may constitute an electrode (for example, an upper electrode) of the storage capacitor Cst, a signal line (for example, a scan line) connected to at least one gate electrode of the transistors T1, T2, and T3, and the like.

A lower metal pattern BML may be disposed under the transistor T.

The lower metal pattern BML may be positioned between the substrate SUB and the buffer layer BFL. The lower metal pattern BML may be electrically connected to the transistor T. A driving range of a voltage supplied to the gate electrode GE of the transistor T can be widened. Although not directly shown in the drawings, the lower metal pattern BML may be electrically connected to the semiconductor pattern SCP of the transistor T to stabilize the channel region of the transistor T. As the lower metal pattern BML may be electrically connected to the transistor T, floating of the lower metal pattern BML may be prevented.

In the above-described embodiments, a case in which the transistor T may be a thin film transistor having a top gate structure has been described as an example, but the disclosure is not limited thereto. A structure of the transistor T may be variously changed.

The display element layer DPL may be provided on the via layer VIA.

The display element layer DPL of each pixel PXL may include first and second alignment electrodes ALE1 and ALE2, the light emitting element LD_1, and the first and second pixel electrodes PE1 and PE2 disposed in the emission area EA.

The display element layer DPL may further include insulating patterns and/or insulating layers sequentially disposed on one surface of the pixel circuit layer PCL. For example, the display element layer DPL may further include a support pattern SPP, a first insulating layer INS1, a bank layer BNK, a second insulating layer INS2, a third insulating layer INS3, a fourth insulating layer INS4, and an organic insulating layer OINS that may be sequentially stacked on each other.

The support pattern SPP (also referred to as a bank pattern or a wall pattern) may be provided on the via layer VIA.

In an embodiment, the support pattern SPP may be formed as a separate pattern that may be individually disposed under the first and second alignment electrodes ALE1 and ALE2 to overlap a portion of each of the first and second alignment electrodes ALE1 and ALE2.

The support pattern SPP may have openings or recesses corresponding to areas between the first and second alignment electrodes ALE1 and ALE2 in the emission area EA, and may be formed of an integrated pattern connected as a whole in the display area DA.

An area of each of the first and second alignment electrodes ALE1 and ALE2 disposed on the support pattern SPP may protrude in a thickness direction of the substrate SUB.

The support pattern SPP may be an inorganic layer including an inorganic material or an organic layer including an organic material. According to an embodiment, the support pattern SPP may include an organic layer composed of a single layer and/or an inorganic layer composed of a single layer, but the disclosure is not limited thereto. According to an embodiment, the support pattern SPP may be provided in a form of a multi-layer in which at least one organic layer and at least one inorganic layer may be stacked on each other. The shape of the support pattern SPP may be variously changed within a range capable of improving the efficiency of light emitted from the light emitting element LD_1.

The support pattern SPP may be used as a reflective member. For example, the support pattern SPP may be used as a reflective member for improving light output efficiency of the pixel PXL by guiding the light emitted from the light emitting element LD_1 in a desired direction.

The first and second alignment electrodes ALE1 and ALE2 may be provided on the support pattern SPP. The first alignment electrode ALE1 and the second alignment electrode ALE2 may be spaced apart from each other. The first alignment electrode ALE1 and the second alignment electrode ALE2 may be disposed on the same plane. For example, the first alignment electrode ALE1 and the second alignment electrode ALE2 may be simultaneously formed in the same process.

Each of the first alignment electrode ALE1 and the second alignment electrode ALE2 may have a shape corresponding to the profile of the support pattern SPP disposed thereunder.

The first alignment electrode ALE1 and the second alignment electrode ALE2 may be formed of a material having a constant (or uniform) reflectance so that the light emitted from the light emitting element LD_1 travels in an image display direction of the display device. For example, the first alignment electrode ALE1 and the second alignment electrode ALE2 may be formed of a conductive material. For example, the first alignment electrode ALE1 and the second alignment electrode ALE2 may include a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and/or an alloy thereof.

The first alignment electrode ALE1 and the second alignment electrode ALE2 may be provided and/or formed of a single layer, but the disclosure is not limited thereto. For example, the first alignment electrode ALE1 and the second alignment electrode ALE2 may be formed of a multi-layer including at least a double layer to minimize distortion due to signal delay in case that a signal is transmitted to both ends EP1 and EP2 of the light emitting element LD_1.

The first insulating layer INS1 may be disposed on the first and second alignment electrodes ALE1 and ALE2.

The first insulating layer INS1 may be provided on an entire surface of the first and second alignment electrodes ALE1 and ALE2 and the support pattern SPP. According to an embodiment, the first insulating layer INS1 may be formed on an entire surface of the display area DA in which the first and second alignment electrodes ALE1 and ALE2 may be formed, and may include openings exposing a portion of each of the first and second alignment electrodes ALE1 and ALE2. The first and second alignment electrodes ALE1 and ALE2 may be electrically connected to the first and second pixel electrodes PE1 and PE2 through the openings, respectively.

The first insulating layer INS1 may be formed of an inorganic insulating layer made of an inorganic material. For example, the first insulating layer INS1 may be formed of an inorganic insulating layer suitable for protecting the light emitting elements LD from the pixel circuit layer PCL. For example, the first insulating layer INS1 may include at least one of silicon nitride (SiNx), silicon oxide (SiOx), silicon oxynitride (SiOxNy), and a metal oxide such as aluminum oxide (AlOx).

According to an embodiment, the first insulating layer INS1 may be provided as a single layer or a multi-layer. In case that the first insulating layer INS1 is provided as a multi-layer, the first insulating layer INS1 may be provided in a distributed Breg reflector (DBR) structure in which first and second layers having different refractive indices and made of an inorganic film may be alternately stacked on each other.

The bank layer BNK may be disposed on the first insulating layer INS1. The bank layer BNK may be provided and/or formed on the first insulating layer INS1 in a non-emission area NEA. A first bank BNK1 may be a pixel defining layer that surrounds the emission area EA and may be formed between adjacent pixels PXL to partition the emission area EA of each of the pixels PXL. For example, the bank layer BNK may include an opening OP corresponding to the emission area EA.

In an operation of supplying (or inputting) the light emitting element LD_1 to the emission area EA, the bank layer BNK may function as a dam structure to prevent a solution (or ink) mixed with the light emitting element LD_1 from following into the emission area EA of an adjacent pixel PXL or to control so that an appropriate amount of solution may be supplied to each emission area EA.

The bank layer BNK may be configured to include at least one light blocking material and/or a reflective material (or a scattering material) to prevent light leakage defects between the pixels PXL. According to an embodiment, a separated reflective material layer may be provided and/or formed on the bank layer BNK to further improve the efficiency of light emitted from the pixel PXL.

Light emitting elements LD_1 may be supplied to the emission area EA of the pixel PXL surrounded (or defined) by the bank layer BNK. For example, the light emitting elements LD_1 may be supplied (or inputted) to the emission area EA by an inkjet printing method or the like, and each of the light emitting elements LD_1 may be aligned on a surface of the first insulating layer INS1 between the first alignment electrode ALE1 and the second alignment electrode ALE2 by an electric field formed by a signal (or an alignment signal) applied to the first alignment electrode ALE1 (or a first alignment line before being separated as the first alignment electrode ALE1) and the second alignment electrode ALE2 (or a second alignment line before being separated as the second alignment electrode ALE2). For example, each of the light emitting elements LD_1 may be arranged such that a first end EP1 faces the first alignment electrode ALE1 and a second end EP2 faces the second alignment electrode ALE2.

In the emission area EA, the second insulating layer INS2 (or an insulating pattern) may be provided and/or formed on the light emitting element LD_1. The second insulating layer INS2 may partially cover an outer peripheral surface (or a surface) of the light emitting element LD_1 to expose the first end EP1 and the second end EP2 of the light emitting element LD_1 to the outside.

The second insulating layer INS2 may include an inorganic insulating layer including an inorganic material or an organic insulating layer. For example, the second insulating layer INS2 may include an inorganic insulating layer suitable for protecting the active layer 12 of each of the first and second light emitting elements LD1 and LD2 from external oxygen, moisture, and the like.

Since the second insulating layer INS2 may be formed on the aligned light emitting element LD_1, the light emitting element LD_1 can be fixed and can be prevented from being separated from the aligned position.

The first pixel electrode PE1 and the second pixel electrode PE2 may be provided to be respectively connected to (or contacted by) the first and second ends EP1 and EP2.

In FIG. 7, the first alignment electrode ALE1 and the first pixel electrode PE1 are shown as electrically separated (or not connected), but the first alignment electrode ALE1 and the first pixel electrode PE1 may be electrically connected to each other through at least one contact hole in an area not shown. Similarly, the second alignment electrode ALE2 and the second pixel electrode PE2 may be electrically connected to each other through at least one contact hole in an area not shown.

The first pixel electrode PE1 may be disposed on the first insulating layer INS1 to overlap a portion of the first alignment electrode ALE1, and the second pixel electrode PE2 may be disposed on the first insulating layer INS1 to overlap a portion of the second alignment electrode ALE2.

The first pixel electrode PE1 and the second pixel electrode PE2 may be formed on the same or different layers. For example, a mutual position and/or a formation order of the first pixel electrode PE1 and the second pixel electrode PE2 may be variously changed according to embodiments.

In an embodiment, as shown in FIG. 7, the second pixel electrode PE2 may be disposed on the first and second insulating layers INS1 and INS2. The second pixel electrode PE2 may be in direct contact with or electrically connected to the second end EP2 of the light emitting element LD1.

The third insulating layer INS3 may be disposed to cover the second pixel electrode PE2. In an embodiment, the third insulating layer INS3 may be in contact with portions of the first insulating layer INS1 and the second insulating layer INS2. For example, the third insulating layer INS3 may be disposed on the first and second insulating layers INS1 and INS2. The third insulating layer INS3 may include an inorganic insulating layer made of an inorganic material or an organic insulating layer made of an organic material. For example, the third insulating layer INS3 may include at least one of silicon nitride (SiNx), silicon oxide (SiOx), silicon oxynitride (SiOxNy), and a metal oxide such as aluminum oxide (AlOx), but the disclosure is not limited thereto.

The first pixel electrode PE1 may be disposed on a portion of the third insulating layer INS3, and may be in direct contact with or electrically connected to the first end EP1 of the light emitting element LD_1. As described above, after the second pixel electrode PE2 may be formed, the first pixel electrode PE1 may be formed. In case that electrodes disposed on the first end EP1 and the second end EP2 of the light emitting element LD_1 are disposed on different layers, the electrodes can be stably separated and short-circuit defects can be prevented. However, this is only an example, and the first pixel electrode PE1 and the second pixel electrode PE2 may be formed on the same layer by the same process.

The first pixel electrode PE1 and the second pixel electrode PE2 may be formed of various transparent conductive materials so that light emitted from the light emitting element LD_1 travels in the image display direction of the display device DD without loss. For example, the first pixel electrode PE1 and the second pixel electrode PE2 may include at least one of various transparent conductive materials such as indium tin oxide (ITO), indium zinc oxide (IZO), zinc oxide (ZnOx), indium gallium zinc oxide (IGZO), and indium tin zinc oxide (ITZO), and may be substantially transparent or translucent to satisfy a light transmittance. However, this is only an example, and the first pixel electrode PE1 and the second pixel electrode PE2 may be formed of various opaque conductive materials.

The fourth insulating layer INS4 may cover the exposed first pixel electrode PE1. In an embodiment, in terms of process convenience, the fourth insulating layer INS4 may be integrally formed over the entire display area DA. Accordingly, the fourth insulating layer INS4 may be in contact with the exposed portion of the first insulating layer INS1, the third insulating layer INS3, the first pixel electrode PE1, and the bank layer BNK.

The organic insulating layer OINS may be provided on the bank layer BNK and the fourth insulating layer INS4 to fill the opening OP. The organic insulating layer OINS may alleviate a step difference caused by components disposed thereunder, and may have a substantially flat upper surface. The organic insulating layer OINS may include an organic layer including an organic material. For example, the organic material may include at least one of an acrylic resin (polyacrylates resin), an epoxy resin, a phenolic resin, a polyamides resin, a polyimides rein, an unsaturated polyester resin, a polyphenylene ethers resin, a polyphenylene sulfides resin, and a benzocyclobutene resin.

The optical auxiliary layer OAL may be provided on the organic insulating layer OINS. In an embodiment, the optical auxiliary layer OAL may include a first color filter layer CF1, a second color filter layer CF2, a third color filter layer CF3, and a polarization layer POL.

The first color filter layer CF1 may be disposed on the organic insulating layer OINS to correspond to the emission area EA and the non-emission area NEA. The first color filter layer CF1 may include a color filter material that transmits light corresponding to the color (or wavelength) emitted from the light emitting element LD_1. For example, in case that the light emitting element LD_1 emits red light, the first color filter layer CF1 may include a red color filter.

In an embodiment, the first, second, and third color filter layers CF1, CF2, and CF3 may be disposed to overlap each other in the non-emission area NEA to block optical interference between adjacent pixels. For example, the first, second, and third color filter layers CF1, CF2, and CF3 may be a red color filter layer, a green color filter layer, and a blue color filter layer, respectively. Accordingly, a stacked structure of the first, second, and third color filter layers CF1, CF2, and CF3 in the non-emission area NEA may prevent color mixing of light emitted between adjacent pixels.

The first, second, and third color filter layers CF1, CF2, and CF3 may include a polymer material having a low reflectance.

The display device DD according to the embodiments of the disclosure may have a structure in which a color conversion layer including color conversion particles made of quantum dots may be omitted. Since the support pattern SPP may be formed higher than the position where the light emitting element LD_1 may be disposed, a luminance difference may occur depending on a viewing angle, and in particular, a problem of lowering side visibility (white angular efficiency; WAD) may occur.

In an embodiment, in order to improve the problem of lowering the side visibility, the first color filter layer CF1 corresponding to the emission area EA of the pixel including the light emitting element LD_1 may include first scatterers SC1. The first scatterers SC1 may be uniformly dispersed in the first color filter layer CF1. The first color filter layer CF1 may be formed on the organic insulating layer OINS in a state in which the first scatterers SC1 may be injected or mixed in a photosensitive resin (for example, a polymer photosensitive resin) forming the first color filter layer CF1.

In an embodiment, the first scatterers SC1 may include at least one of TiO₂, ZnO, Al₂O₃, SiO₂, hollow silica, and polystyrene particles. For example, the first scatterers SC1 may include TiO₂. However, this is only an example, and the material of the first scatterers SC1 is not limited thereto.

In an embodiment, the first scatterers SC1 may be spherical or elliptical spherical particles. However, this is only an example, and shapes of the first scatterers SC1 are not limited thereto.

The first scatterers SC1 may scatter light incident to the first color filter layer CF1 from the emission area EA of the display element layer DPL. Accordingly, as light emitted to the outside of the display device DD may be scattered, the color difference according to the viewing angle or the luminance difference according to the viewing angle may be reduced. For example, the side visibility (e.g., WAD) may be improved. Since scatterers may be applied in a color filter layer without adding a separate member for scattering light, the thickness of the display device DD can be reduced.

However, reflectance of external light may be increased by the first scatterers SC1. For example, compared to a conventional case in which scatterers may not be applied, reflectance of a display device including a color filter to which scatterers may be applied may be higher, and reflection by the scatterers may be 80% or more of the reflectance. Since image quality may be reduced in case that the reflectance of external light is increased, the polarization layer POL may be disposed on the first, second, and third color filter layers CF1, CF2, and CF3 to reduce the reflectance of external light.

The polarization layer POL may be integrally formed over the emission area EA and the non-emission area NEA. The polarization layer POL may control the transmittance (or absorption rate) of external light. For example, the polarization layer POL may reduce the amount of external light incident to the first, second, and third color filter layers CF1, CF2, and CF3.

In an embodiment, the polarization layer POL may be a coating-type polarization layer (coating polarization layer) including a dichroic dye. For example, the polarization layer POL may be formed on the first, second, and third color filter layers CF1, CF2, and CF3 by a coating method such as slit coating. Accordingly, the polarization layer POL having a very thin thickness can be implemented, and the polarization layer POL can be formed at a lower cost than a conventional method for manufacturing a polarization layer of the circular polarization method.

The polarization layer POL, which may be a coating-type polarization layer, may include a host-guest type polarization layer in which R, G, and B dyes as a guest may be mixed with a liquid crystal as a host, and the R, G, and B dyes may be arranged together in case that the host is arranged according to an alignment direction of a lower alignment layer to absorb light parallel to an alignment direction (absorption direction) of the dye, and transmit light perpendicular to the alignment direction of the dye to polarize light. However, this is only an example, and the polarization layer POL may include a lyotropic polarization layer in which lyotropic polymers may be arranged in a line to polarize light, a wire-grid type polarization layer in which metal nanowires may be arranged in a direction on a base layer and a polarization direction of incident light may be determined according to the arrangement direction of the metal nanowires, or the like.

In an embodiment, the content of the dichroic dye may be greater than about 0.5 wt % and less than about 2 wt % based on a total weight of the polarization layer POL. The light transmittance (or absorption rate) for visible light may vary according to the content of the dichroic dye. For example, in case that the content of the dichroic dye is about 1 wt % based on the total weight, the transmittance (or absorption rate) of external light may be about 50%. Accordingly, the reflectance of external light by the scatterers can be reduced by about 50%.

The encapsulation layer ENC may be provided on the polarization layer POL. The encapsulation layer ENC may include an inorganic insulating layer including an inorganic material and/or an organic insulating layer including an organic material. The encapsulation layer ENC may prevent moisture from flowing into the optical auxiliary layer OAL and the display element layer DPL from the outside by completely covering components disposed thereunder.

In an embodiment, the encapsulation layer ENC (also referred to as a passivation layer or an organic passivation layer) may include an organic material having high hardness. The encapsulation layer ENC may have high hardness properties to withstand external shocks or scratches. The encapsulation layer ENC may planarize a step difference in an upper surface due to the first, second, and third color filter layers CF1, CF2, and CF3.

In an embodiment, the encapsulation layer ENC may be composed of a multi-layer. For example, the encapsulation layer ENC may include at least two inorganic insulating layers and at least one organic insulating layer interposed between the at least two inorganic insulating layers. However, materials and/or structures constituting the encapsulation layer ENC may be variously changed. At least one overcoat layer, filler layer, and/or upper substrate may be further disposed on the encapsulation layer ENC.

As described above, the display device DD according to the embodiments of the disclosure may have a structure in which a color conversion layer including color conversion particles may be omitted. Therefore, the thickness of the display device DD can be reduced and the manufacturing cost can be reduced. Since scatterers may be included in a color filter layer, the color difference/luminance difference according to the viewing angle may be reduced, and the side visibility (e.g., white angular efficiency; WAD) may be improved. Furthermore, the reflectance of external light by the scatterers can be improved by disposing the coating-type polarization layer POL on the color filter layer.

Accordingly, the thickness of the display device DD can be reduced without increasing the manufacturing cost, and image quality such as the side visibility can be improved.

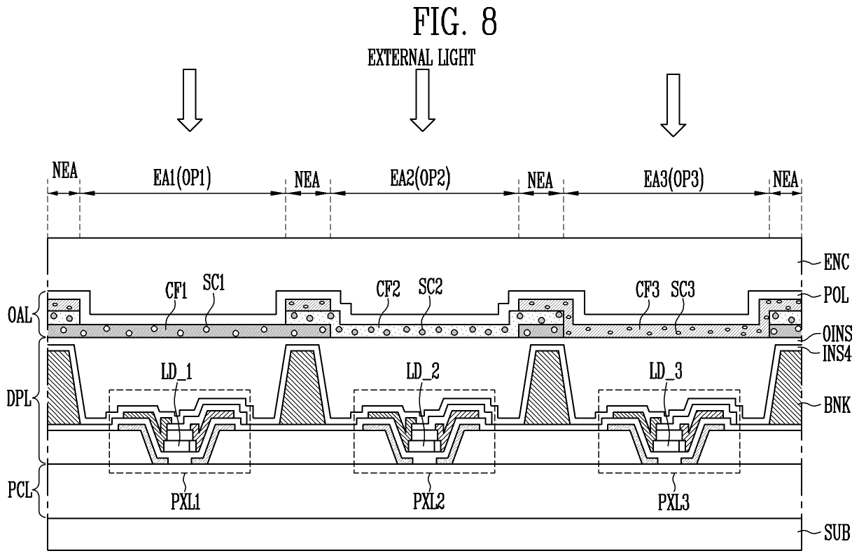

FIG. 8 is a cross-sectional view schematically illustrating an example of the display area of the display device of FIG. 3.

In FIG. 8, the same reference numerals are used for the same or similar components described with reference to FIG. 7, and duplicate descriptions thereof will be omitted. A stacked structure of FIG. 8 may be substantially the same as or similar to the stacked structure of FIG. 7, except for a configuration of a cross-sectional view extending to first to third pixels PXL1, PXL2, and PXL3. Also, for convenience of description, a configuration of the pixel circuit layer PCL is omitted in FIG. 8.

In FIG. 8, a configuration of the optical auxiliary layer OAL will be described.

Referring to FIGS. 1, 2, 3, and 8, the display device DD (or display panel) may include the substrate SUB, the pixel circuit layer PCL, the display element layer DPL, the optical auxiliary layer OAL, and the encapsulation layer ENC (or protective layer).

In an embodiment, the first pixel PXL1 may include a first light emitting element LD_1, the second pixel PXL2 may include a second light emitting element LD_2, and the third pixel PXL3 may include a third light emitting element LD_3. The first light emitting element LD_1 may be disposed in a first emission area EA1 and may emit light of a first color. The second light emitting element LD_2 may be disposed in a second emission area EA2 and may emit light of a second color. The third light emitting element LD_3 may be disposed in a third emission area EA3 and may emit light of a third color.

The first, second, and third light emitting elements LD_1, LD_2, and LD_3 may be light emitting diodes that emit light of different colors and have a size of a micro-scale or less. For example, active layers 12 of the first, second, and third light emitting elements LD_1, LD_2, and LD_3 may include different materials emitting light of different wavelength bands. The first color, the second color, and the third color may be red, green, and blue, respectively. Hereinafter, it may be assumed that the first color is red, the second color is green, and the third color is blue.

The bank layer BNK may surround the first to third emission areas EA1, EA2, and EA3. A portion where the bank layer BNK may be disposed may be defined as the non-emission area NEA. The bank layer BNK may be a pixel defining layer partitioning the first to third emission areas EA1, EA2, and EA3. For example, the bank layer BNK may include first to third openings OP1, OP2, and OP3 corresponding to the first to third emission areas EA1, EA2, and EA3, respectively.

The first color filter layer CF1 may be disposed on the organic insulating layer OINS to overlap the first emission area EA1 and the non-emission area NEA. The first color filter layer CF1 may be formed on the organic insulating layer OINS as an integrated pattern exposing the organic insulating layer OINS of the second emission area EA2 and the third emission area EA3.

The first color filter layer CF1 may include a color filter material that transmits light corresponding to the first color and first scatterers SC1.

After the first color filter layer CF1 may be formed (for example, deposited), the second color filter layer CF2 may be formed (for example, deposited). The second color filter layer CF2 may be disposed to overlap the second emission area EA2 and the non-emission area NEA. The second color filter layer CF2 may not be formed in the first emission area EA1 and the third emission area EA3.

The second color filter layer CF2 may include a color filter material that transmits light corresponding to the second color and second scatterers SC2.

After the second color filter layer CF2 may be formed (for example, deposited), the third color filter layer CF3 may be formed (for example, deposited). The third color filter layer CF3 may be disposed to overlap the third emission area EA3 and the non-emission area NEA. The third color filter layer CF3 may not be formed in the first emission area EA1 and the second emission area EA2. The third color filter layer CF3 may include a color filter material that transmits light corresponding to the third color and third scatterers SC3.

Thicknesses of the first, second, and third color filter layers CF1, CF2, and CF3 may be substantially the same. However, this is only an example, and the thicknesses of the first, second, and third color filter layers CF1, CF2, and CF3 may be set differently in consideration of front luminance and/or side luminance in each of the emission areas EA1, EA2, and EA3.

In an embodiment, the first, second, and third scatterers SC1, SC2, and SC3 may include at least one of TiO₂, ZnO, Al₂O₃, SiO₂, hollow silica, and polystyrene particles. At least two of the first, second, and third scatterers SC1, SC2, and SC3 may include the same material. However, this is only an example, and the first, second, and third scatterers SC1, SC2, and SC3 may include different materials.

In an embodiment, based on the same volume, the content of the first scatterers SC1 included in the first color filter layer CF1 and the content of the second scatterers SC2 included in the second color filter layer CF2 may be different from each other. Also, based on the same volume, the content of the third scatterers SC3 may be different from the content of the first scatterers SC1 and the content of the second scatterers SC2.

For example, under the same content condition, a reduction rate of front luminance in an area that transmits light in a relatively long wavelength region may be low. Accordingly, the content of the scatterers may be differently controlled according to the wavelength of the emitted light. For example, the content of the first scatterers SC1 may be greater than the content of the second scatterers SC2, and the content of the second scatterers SC2 may be greater than the content of the third scatterers SC3.

In an embodiment, at least one of the size of the first scatterer SC1, the size of the second scatterer SC2, and the size of the third scatterer SC3 may be different.

At least one of the materials constituting the scatterers, the content of the scatterers, the thicknesses of the scatterers, and the thickness of the color filter layer may be set in consideration of deviations in front luminance and side luminance for emission areas.

The polarization layer POL may be disposed to cover all of the first, second, and third color filter layers CF1, CF2, and CF3. The polarization layer POL may be integrally formed over the first emission area EA1, the second emission area EA2, the third emission area EA3, and the non-emission area NEA. For example, the polarization layer POL may be integrally formed to cover an entire surface of the display area DA. In an embodiment, the polarization layer POL may be a coating-type polarization layer including a dichroic dye. For example, the polarization layer POL may be formed on the first, second, and third color filter layers CF1, CF2, and CF3 by a coating method such as slit coating. The coating-type polarization layer POL may reduce the amount of external light incident to the first, second, and third color filter layers CF1, CF2, and CF3. Accordingly, reflection of external light by the first, second, and third scatterers SC1, SC2, and SC3 can be reduced.

As described above, the display device according to the embodiments of the disclosure may have a thinned structure in which a color conversion layer including color conversion particles (for example, quantum dots) may be omitted, and scatterers may be included in a color filter layer. Therefore, the color difference/luminance difference according to the viewing angle may be reduced, and the side visibility (e.g., WAD) may be improved. The reflection of external light by the scatterers may be reduced or minimized by disposing a coating-type polarization layer on the color filter layer.

Accordingly, the thickness of the display device may be reduced, the side visibility may be improved, and the reflection of external light may be reduced without increasing the manufacturing cost.

However, effects of the disclosure are not limited to the above-described effects, and may be variously extended without departing from the spirit and scope of the disclosure.

As described above, embodiments of the disclosure have been described with reference to the drawings. However, those skilled in the art will appreciate that various modifications and changes can be made to the embodiments without departing from the spirit and scope of the disclosure.

What is claimed is:

1. A display device comprising:
a first light emitting element disposed in a first emission area and forming a first pixel;
a second light emitting element disposed in a second emission area and forming a second pixel;
a bank layer including:
a first opening corresponding to the first emission area;
a second opening corresponding to the second emission area; and
a non-emission area partitioning the first emission area and the second emission area;
a first color filter layer disposed on the first light emitting element and the bank layer and including first scatterers;
a second color filter layer disposed on the second light emitting element and the bank layer and including second scatterers; and
a polarization layer disposed on the first color filter layer and the second color filter layer.

2. The display device of claim 1, wherein
the first light emitting element is a light emitting diode having a size less than or equal to a micro-scale, the first light emitting element emitting light of a first color, and
the second light emitting element is a light emitting diode having a size less than or equal to a micro-scale, the second light emitting element emitting light of a second color different from the first color.

3. The display device of claim 2, wherein the polarization layer is a coating polarization layer including a dichroic dye.

4. The display device of claim 3, wherein content of the dichroic dye is greater than about 0.5 wt % and less than about 2 wt % based on a total weight of the polarization layer.

5. The display device of claim 2, wherein content of the first scatterers and content of the second scatterers are different from each other with respect to a same volume.

6. The display device of claim 2, wherein sizes of the first scatterers and sizes of the second scatterers are different from each other.

7. The display device of claim 2, further comprising:
a third light emitting element disposed in a third emission area and forming a third pixel; and
a third color filter layer disposed on the third light emitting element and the bank layer and including third scatterers,
wherein the bank layer further includes an opening corresponding to the third emission area.

8. The display device of claim 7, wherein the third light emitting element is a light emitting diode having a size less than or equal to a micro-scale, the third light emitting element emitting light of a third color different from the first color and the second color.

9. The display device of claim 8, wherein the polarization layer is integrally formed to overlap the first emission area, the second emission area, the third emission area, and the non-emission area.

10. The display device of claim 9, wherein the first color filter layer, the second color filter layer, and the third color filter layer are sequentially stacked on each other to overlap the bank layer.

11. The display device of claim 10, wherein the polarization layer is directly disposed on the first color filter layer, the second color filter layer, and the third color filter layer in the first emission area, the second emission area, and the third emission area.

12. The display device of claim 9, wherein content of the first scatterers, content of the second scatterers, and content of the third scatterers are different from each other with respect to a same volume.

13. The display device of claim 9, wherein each of the first to third pixels includes:
a first alignment electrode and a second alignment electrode that are disposed to be spaced apart from each other with each of the first to third light emitting elements interposed therebetween;
a first pixel electrode electrically connected to the first alignment electrode and an end of each of the first to third light emitting elements,
the first pixel electrode disposed on the first alignment electrode with an insulating layer interposed therebetween; and
a second pixel electrode electrically connected to the second alignment electrode and another end of each of the first to third light emitting elements, the second pixel electrode disposed on the second alignment electrode with the insulating layer interposed therebetween.

14. The display device of claim 13, further comprising:
an organic insulating layer disposed on the bank layer to fill the first to third openings and planarizing lower surfaces of the first to third color filter layers.

15. A display device comprising:
a first light emitting element disposed in a first emission area and forming a first pixel;
a second light emitting element disposed in a second emission area and forming a second pixel;
a third light emitting element disposed in a third emission area and forming a third pixel;
a bank layer including:
a first opening corresponding to the first emission area;
a second opening corresponding to the second emission area;
a third opening corresponding to the third emission area, and;
a non-emission area partitioning the first emission area, the second emission area, and the third emission area;
a first color filter layer disposed on the first light emitting element and the bank layer and including first scatterers;
a second color filter layer disposed on the second light emitting element and the bank layer and including second scatterers;
a third color filter layer disposed on the third light emitting element and the bank layer and including third scatterers; and
a coating polarization layer integrally disposed on the first color filter layer, the second color filter layer, and the third color filter layer.

16. The display device of claim 15, wherein
the first light emitting element is a light emitting diode having a size less than or equal to a micro-scale, the first light emitting element emitting light of a first color,
the second light emitting element is a light emitting diode having a size less than or equal to a micro-scale, the second light emitting element emitting light of a second color different from the first color, and
the third light emitting element is a light emitting diode having a size less than or equal to a micro-scale, the third light emitting element emitting light of a third color different from the first color and the second color.

17. The display device of claim 16, wherein the coating polarization layer includes a dichroic dye.

18. The display device of claim 17, wherein content of the dichroic dye is greater than about 0.5 wt % and less than about 2 wt % based on a total weight of the polarization layer.

19. The display device of claim 17, wherein the first color filter layer, the second color filter layer, and the third color filter layer are sequentially stacked on each other to overlap the bank layer.

20. The display device of claim 19, wherein the polarization layer is directly disposed on the first color filter layer, the second color filter layer, and the third color filter layer in the first emission area, the second emission area, and the third emission area.
